(19) United States
(12) Patent Application Publication
(10) Pub. No.: US 2007/0023877 A1
(43) Pub. Date: Feb. 1, 2007

(54) Chip on flex tape with dimension retention pattern

(76) Inventor: Hideo Yamazaki, Tokyo (JP)

Correspondence Address: 3M INNOVATIVE PROPERTIES COMPANY, PO BOX 33427, ST. PAUL, MN, 55133-3427, US

(21) Appl. No.: 10/570,980

(22) PCT Filed: Aug. 3, 2004
(86) PCT No.: PCT/US04/24986

§ 371 Date: Mar. 8, 2006

(30) Foreign Application Priority Data
Sep. 10, 2003 (JP) 2003/18639

(51) Int. Cl. H01L 23/495

(52) U.S. Cl. 257/668

(57) ABSTRACT

To provide a chip on flex (COF) tape having an improved precision of cumulative pitches while retaining bending properties. [Means to Solve the Problems] A chip on flex (COF) tape having a wiring pattern comprising a plurality of wirings arranged in parallel formed on the surface of a flexible insulating film, wherein a dimension retention pattern is formed on said surface of said flexible insulating film and/or the surface of the side of the film opposite thereto so as to cross the width direction of at least two of said wirings arranged in parallel in the vicinity of the connecting portion of said wiring pattern with a semiconductor chip and/or the connecting portion with an external device.

### TECHNICAL FIELD OF THE INVENTION

The present invention relates to chip on flex (COF) tapes for semiconductor devices in which semiconductor chips are mounted on a flexible substrate.

### BACKGROUND ART

Semiconductor devices having semiconductor chips mounted on a flexible substrate have been widely used for the wiring and connection of various electronic device products such as personal computers, terminal devices of personal computers, hard disk drives (HDD), personal digital assistants (PDA), digital versatile disks (D)VD), mobile phones, and liquid crystal display panels (LCD). As such semiconductor devices, there can be illustrated the tape carrier package (TCP) that is conventionally used and the chip on flex (COF) (also referred to as “chip on film”) that has come to be frequently used in recent years. In each field of the above products, higher density in the mounting of electronic devices and larger display panels have been keenly sought, and in integrated circuit (IC) packages for liquid crystal displays (LCD), there are increasing demands for finer pitches, higher resolutions, and increased capability in tape bending. In order to satisfy these demands, the conventional tape carrier package (TCP) is being replaced with the chip on flex (COF).

Tape carrier package (TCP) tapes have device holes for mounting integrated circuit (IC) chips. IC chips disposed in such device holes are electrically connected at the connecting portion of the lead termed as an inner lead made of thin metal wires and is present in the form of a so-called “flying lead.” On the other hand, chip on flex (COF) tapes have no device holes, and IC chips are mounted on the tape and are directly connected to the connecting portion of the inner lead present as a wiring layer on the tape, and therefore finer pitches can be attained more easily than in the TCP tapes.

In order to house various products into a prescribed place after mounting a chip on flex (COF) tape, generally the COF tape has to be bent. In order to facilitate bending and to minimize repulsion after bending, a two-layered chip on flex (COF) tape has been generally used which comprises a thin (25 or 38 μm in thickness) flexible insulating film as a substrate and, thereupon, a metal layer has been attached as a wiring layer. Such two-layered COF tapes have been produced by a method of growing a metal layer in which the metal layer is formed on a flexible insulating film such as polyimide, a casting method in which a resin film precursor such as polyimide varnish is coated on the surface of a metal foil followed by heat treatment for curing and solvent removal, or an adhesion method in which a metal foil such as a copper foil and a flexible insulating film such as a polyimide film are laminated by means of an appropriate adhesive means such as a thermoplastic polyimide adhesive. From the viewpoint of circuit formation, such two-layered COF tapes have been generally produced by an additive method in which a resist pattern is formed on a flexible insulating film and then in the resist pattern gaps a wiring metal such as copper is grown, a semi-additive method in which an electrode metal layer such as copper is formed on a flexible film so as to form a resist pattern, and then a metal wiring such as copper is grown by using the electrode metal layer as the feeding layer, a subtract method in which, from a laminate of a metal layer and a flexible insulating film, the metal layer is etched in a wiring pattern image so as to form a wiring circuit on a flexible insulating film, and the like.

Generally a COF tape has a circuit wiring applied on the surface of a flexible insulating film (mainly a polyimide film), and is used with semiconductor chips mounted thereon such as integrated circuits (IC) for drivers for flat display panels such as liquid crystal display panels (LCD), plasma display panels (PDP), organic eletroluminescence (EL) displays and the like. A COF tape is mounted with the connecting portion (generally referred to as “outer lead”) for connecting to a display panel element portion or a printed circuit board, and with the chip connecting portion (generally referred to as “inner lead”) for connecting to an integrated circuit (IC).

In order to enhance reliability in finer pitches, measures have been taken conventionally to improve adhesive properties at the connecting portion, to prevent wire breaking, and the like. In Japanese Unexamined Patent Publication (Kokai) No. 2001-201757, for example, in a liquid crystal display device in which a plurality of outer lead terminals for connection to the liquid crystal display portion and outer lead terminals to the drive circuit portion have been connected by an anisotropic conductive film (ACF), a reinforcement member has been disposed in the vicinity of the outer lead terminals for connection to the liquid crystal display portion so as to disperse and alleviate stresses generated in the tape. This led to an improved adhesive property of the outer lead with the anisotropic conductive film (ACF) and an enhanced reliability of electrical connection.

Japanese Unexamined Patent Publication (Kokai) No. 2002-124544 discloses the formation of a dummy lead in between two adjacent inner leads in parallel with the wiring direction of these two inner leads. This has attempted to prevent the breaking of the inner lead portion due to heat stress.

On the other hand, though chip on flex (COF) tapes require capability in bending, wire breaking due to bending may occur more often as the pitch of the circuit becomes finer, thereby leading to a tendency to reduced capability in bending. Accordingly, though relatively rigid polyimide films having a thickness of 50 and 75 μm are used in order to enhance capability in bending of tapes in Japanese Unexamined Patent Publication (Kokai) No. 5-3228 and Japanese Patent No.3169039, bending properties have been enhanced by removing the polyimide in a slit form at the bending portion, and then coating the exposed copper lead with a flexible resin. Furthermore, in Japanese Unexamined Patent Publication (Kokai) No. 10-32227, bending properties have been improved by making thinner the thickness of the copper lead at the bending portion. Furthermore, in Japanese Unexamined Patent Publication (Kokai) No. 2001-53108, the use of a thin base film having excellent bending properties have been made possible by sticking a plastic reinforcement film to the reverse surface of a COF tape.

It can be seen, as described above, that as the pitches of wiring circuits of COF tapes become increasingly finer, conventional art has exercised various contrivances to prevent wire breaking and to maintain bending properties. However, due to finer pitches of wiring circuits, small deviations in the distance between a plurality of leads (cumulative pitch) have rendered it difficult to join the connecting portion of lead connecting terminals with semiconductor chips or with the connecting portion of display portions.

Generally, in laminates of a metal layer and a flexible insulating film which become a material for COF tapes, there are residual internal stresses due to conditions such as tension and heat during laminate fabrication. Such stresses are released at areas having no metal layers during the formation of wiring patterns, and causes expansion or shrinkage leading to changes in dimension. Stresses in such a flexible insulating film vary with regions on the surface thereof, and thus it is difficult to predict the dimensional changes. Furthermore, since the thermal expansion coefficients of semiconductor chips or display panels are different from those of flexible insulating films (for example polyimide) of COF tapes, cumulative pitches on the COF tapes become different at the time of wiring formation from those at the time of heating for semiconductor chip mounting or display panel connection, and hence such dimensional changes should be considered in designing of COF in advance.

Reinforcement members and dummy leads described in Japanese Unexamined Patent Publication (Kokai) No. 2001-201757 and Japanese Unexamined Patent Publication (Kokai) No. 2002-124544 may indeed exhibit an effect of inhibiting thermal stress generated in parallel with the direction of wiring so as to prevent wire breaking, but they cannot prevent unpredictable dimensional changes in cumulative pitches. Thus, the prior art cannot improve the precision of cumulative pitches. Furthermore, since reinforcement members and dummy leads described do not extend in between a plurality of wirings, the overall thermal expansion coefficient of COF in the direction across the wirings becomes relatively large due to contribution from a thermal expansion coefficient of a flexible insulating film.

### DISCLOSURE OF THE INVENTION

[Problems to be Solved by the Invention]

Thus, it is an object of at least one embodiment of the present invention to provide a chip on flex (COF) tape having an improved precision of cumulative pitch while retaining bending properties.

[Means to Solve the Problems]

According to one aspect of the present invention, there is provided a chip on flex (COF) tape having a wiring pattern comprising a plurality of wirings arranged in parallel formed on the surface of a flexible insulating film, wherein a dimension retention pattern is formed on said surface of said flexible insulating film and/or the surface of the side of the film opposite thereto so as to cross the width direction of at least two of said wirings arranged in parallel in the vicinity of the connecting portion of said wiring pattern with a semiconductor chip and/or with an external device.

### EFFECT OF THE INVENTION

Such a tape can prevent unpredictable dimensional deviations in the cumulative pitch due to the thermal expansion or shrinking of the flexible insulating film. As a result, even a tape having wirings with fine pitches can be connected to semiconductor chips and external devices (for example, display panels and printed boards) with a high connection reliability. It is also possible to incorporate expected dimensional changes during heating in designing since the thermal expansion coefficient of the COF tape between cumulative pitches corresponds to that of the dimension retention pattern.

### BRIEF DESCRIPTION OF THE DRAWINGS

FIG. 1 shows a top view of one aspect of the chip on flex (COF) tape.

FIGS. 2(a), 2(b), 2(c) and 2(d) show an enlarged top view of the inner lead portion of the COF tape of the present invention;

FIGS. 3(a) and 3(b) show an enlarged top view of the outer lead portion of the COF tape of the present invention;

FIGS. 4(a), 4(a′), 4(b), 4(b′), 4(c), 4(c′), 4(d), 4(d′), 4(e), 4(e′), 4(f) and 4(f′) show top views of the COF tape of the present invention and cross-section views;

FIG. 5 shows the results of investigation on dimensional changes of the samples in Working Example 1 before and after etching (control sample);

FIG. 6 shows the results of investigation on dimensional changes of the samples in Working Example 1 before and after etching (the sample of the present invention);

FIG. 7 shows the relationship of thickness and linear expansion coefficient of the copper layer for each polyimide thickness.

### BEST MODE FOR CARRYING OUT THE INVENTION

Now preferred embodiments of the chip on flex (COF) tape of the present invention will be explained hereinbelow.

As used herein the term “the vicinity of the connecting portion” means a region which is near the connecting portion but is not substantially in contact therewith. In particular, if a dimension retention pattern is present on the surface having the wiring pattern of the film (the front side), it is a range in which wirings of the wiring pattern do not short-circuit with each other. If a dimension retention pattern is present on the surface having no wiring pattern of the film (the opposite side or the back side), it is a range corresponding to directly under or around the connecting portion.

The term “wiring pattern” means an assembly of a plurality of wirings formed on a flexible insulating film.

The term “the connecting portion of a wiring pattern” means a connecting portion corresponding to the terminal region (lead) of wirings, and includes the connecting portion of an inner lead connecting with semiconductor chips and an outer lead connecting portion connecting with external devices such as display panels or printed circuit boards.

The term “to cross or being across the width direction of at least two wirings arranged in parallel” means to extend for a length at least the same as that of the straight line substantially along the direction of a line extending between or among the connecting portions (leads) of two or more parallel wirings.

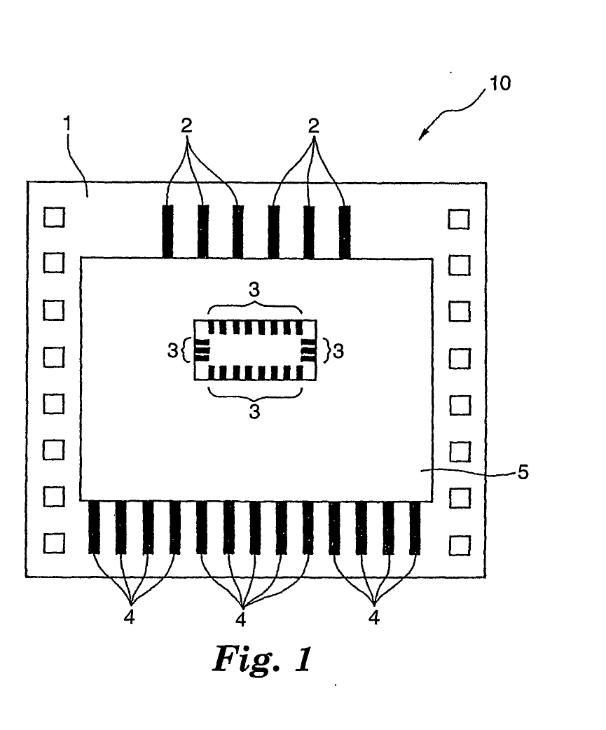

Embodiments of the present invention will now be explained with reference to drawings. It should be noted, however, that the present invention is not limited by these specific embodiments. FIG. 1 shows a top view of one embodiment of a chip on flex (COF) tape. The illustrated chip on flex (COF) tape 10 shows a driver for a flat panel display formed in the form of a TAB tape as an example. A wiring pattern has been formed on a flexible insulating film 1 (tape substrate). The wiring is connected from the input side outer lead 2 (the connecting portion for input) to the inner lead 3 (the connecting portion to the semiconductor chip), which is further connected from the inner lead 3 to the output side outer lead 4 (the connecting portion for output). Although not shown, the input side outer lead 2 is connected to a printed circuit board, and, on the other hand, the output side outer lead 4 is connected to the display panel. The wiring portion except the input side outer lead 2, the inner lead 3, and the output side outer lead 4 is covered with a solder resist (or cover coat) 5 to secure an insulating state.

As the flexible insulating film 1, those flexible resin films that have heat resistance to resist heating at the time of mounting semiconductor chips and other parts, an electrical insulating property to prevent short circuit, and mechanical strength to resist stresses are used. As such a film 1, there can be mentioned for example resin films such as polyimide, polyester, polyamide, polyetherether ketone, polyether sulfone and liquid crystal films, and from a viewpoint of heat resistance, mechanical strength, electrical insulating property, etc., polyimide films are preferred.

A wiring pattern has been formed on a flexible insulating film. A wiring pattern is generally formed from conducting metals such as copper, nickel, chromium, gold, and silver. As shown in FIG. 1, the wiring pattern comprises the input side outer lead 2, the inner lead 3, and the output side outer lead 4 as a plurality of wirings arranged in parallel at the connecting portion of the terminal region.

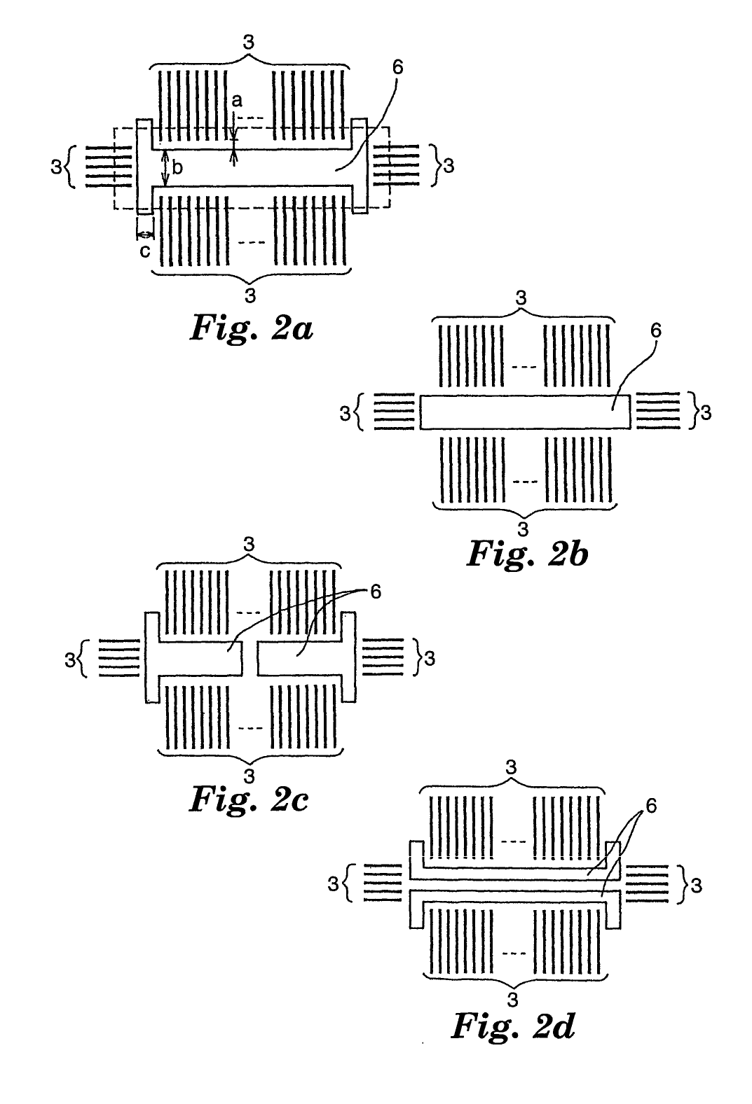

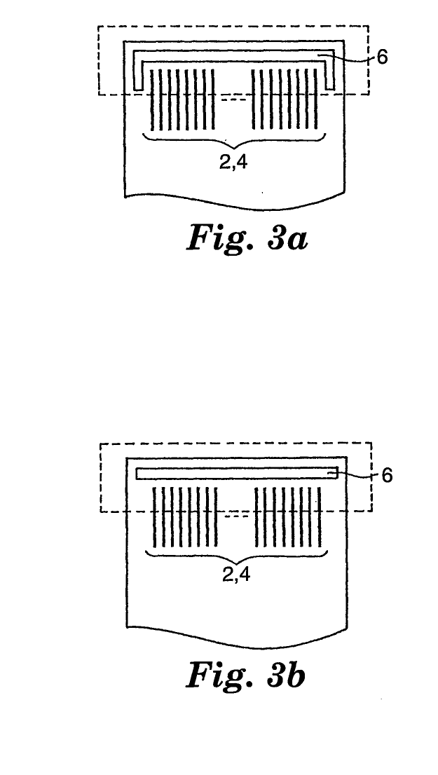

FIGS. 2(a) and 2(b) show an enlarged top view of inner lead portion of the COF tape of the present invention having dimension retention patterns in various forms. In the vicinity of the inner lead 3 made of a plurality of wirings arranged in parallel, there have been arranged a dimension retention pattern 6 on the same surface (the front surface) as the inner lead 3 so as to cross the width direction of at least two wirings. “a” is the distance between inner lead and dimension retension pattern in vertical direction in FIG. 2(a) “b” is the minimum width of dimension retension pattern in vertical direction in FIG. 2(a). “c” is the width of protruded portion dimension retension pattern in horizontal direction, present between most left-sided inner lead among inner leads extending in vertical direction in FIG. 2(a) and inner leads extending in horizontal direction in FIG. 2(a). The size of dimension retention pattern varies, depending on the size of semiconductor chip. “a” in FIG. 2(a) is usually from 15 to 100 μm. FIGS. 3(a) and 3(b) show an enlarged top view of outer lead portion of the COF tape of the present invention. In the vicinity of the outer lead 2 or 4 made of a plurality of wirings arranged in parallel, there have been arranged a dimension retention pattern 6 on the same surface (the front surface) as the outer lead 2 or 4 so as to cross the width direction of at least two wirings. In FIGS. 2(a) to 2(d), regions represented by dotted lines are positions where semiconductor chips are mounted. In FIGS. 3(a) and 3(b), regions represented by dotted lines are positions where display panels are mounted. Initially, stresses have been accumulated in the flexible insulating film due to the effect of tension or heat during film fabrication as a laminate with a metal layer. Such stresses in the film are released during the wiring pattern formation by etching resulting in dimensional changes. Stresses accumulated in films are not uniform throughout the surface of the film, and thus dimensional changes after the releasing of stresses due to heating greatly vary throughout the surface, and are difficult to predict. Furthermore, the thermal expansion coefficient of the film is larger than that of the metal layer, which is larger at higher temperatures (the thermal expansion coefficient (Kapton EN (trade name), manufactured by DuPont) is about 1.0×10⁻⁵/° C. at 60° C., and 1.8×10⁻⁵/° C. at 290° C.). In accordance with the present invention, dimension retention patterns constrain the space between lead pitches, and thus dimensional changes between the lead pitch (the cumulative pitch) of a plurality of leads at bonding and at designing before etching and the cumulative pitch after etching can be suppressed. Although resin films such as polyimide expand by moisture absorption (the thermal expansion coefficient due to moisture change (Kapton EN (trade name), manufactured by DuPont) is about 1.6×10⁻⁵/RH %), there arises reduced expansion due to moisture change because of constrains by dimension retention patterns. This makes it possible to improve the precision of cumulative pitches without a strict moisture control, with a result that semiconductor chips can be connected with an electrical connection reliability.

As the shape of dimension retention patterns, FIG. 2(a) is most effective, but by removing the projections on the left and the right as shown in FIG. 2(b), more leads can be disposed on the same area. Also, by dividing the patterns as shown in FIGS. 2(c) and (d), wirings can be designed at the divided areas.

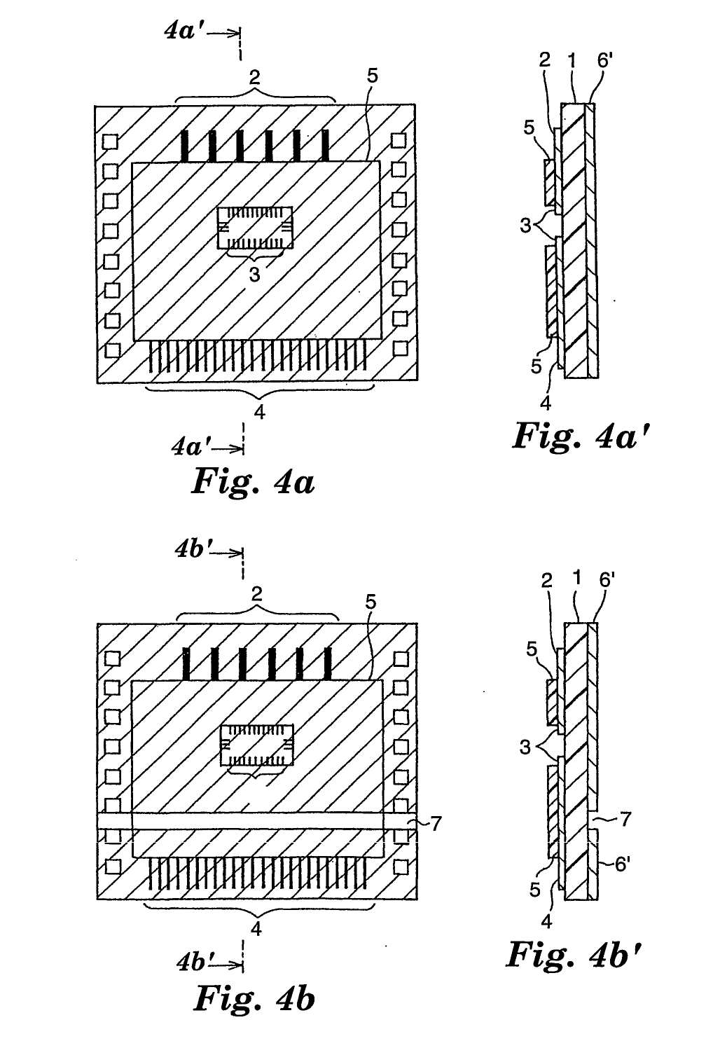

In accordance with another aspect of the present invention, a dimension retention pattern 6′ may be disposed on the surface (the back surface) opposite to the surface on which the wiring pattern of the flexible insulating film I has been formed. FIGS. 4(a) to (4′) (FIG. 4(a) to FIG. 4(f), and FIG. 4(a′) to FIG. 4(f′)) show a top view of a COF tape and a cross section in which areas having a dimension retention pattern 6′ have been diagonally shaded. In FIGS. 4(a) and (a′), a dimension retention pattern 6′ has been disposed throughout the entire surface except the sprocket holes for transporting TAB tapes. In this case, there is no need to further form patterns on the metal layer formed on the entire back surface. In FIGS. 4(b) and (b′), a dimension retention pattern 6′ has been divided into two parts extending in the width direction of the film. Thus, there are slit-shaped area having no patterns 7 in between two dimension retention patterns 6′. In such a case, the film can be bent at this slit position 7, and the bending property can be secured.

In FIGS. 4(c) and (c′), there have been provided areas having no patterns 8 at the marked portion for alignment for use during the mounting of semiconductor chips and the connecting of external devices (display panels), as well as the presence of slit-shaped areas having no patterns 7 as in FIGS. 4(b) and FIG. 4(b′). This makes it easier to align tape patterns by the light transmission method. In FIGS. 4(d) and (d′), there have been provided areas having no patterns 9 at the mounting portion of semiconductor chips and the connecting portion for external devices (display panels), as well as the presence of slit-shaped areas having no patterns 7 as in FIGS. 4(b) and FIG. 4(b′). This makes it possible to observe the connecting portion through the film at the time of mounting. Also, the connecting portion can be effectively heated at the time of mounting. FIGS. 4(e) and (e′) as well as FIGS. 4(f) and (f′) provide dimension retention patterns only in the vicinity of the mounting portion for semiconductor chips and the connecting portion for external devices (display panels). This makes it possible to effect stabilization of dimension of cumulative pitches with little loss of flexibility of the COF tape.

As described above, the dimension retention pattern of the present invention has been formed so as to cross the width direction of at least two wirings arranged in parallel in the vicinity of the connecting portion of the wiring pattern. Extending by crossing the width direction of two or more wirings arranged in parallel physically constrains the wirings. As a result, no increases in cumulative pitches of adjacent wirings to an unpredictable amount would occur even at the time of etching for wiring pattern formation or during bonding. In order to permit the manifestation of such functions, it is preferred that the dimension retention pattern has a property similar to that of the material constituting the wiring pattern. The quality of the material or the thickness of the dimension retention pattern may be different from those of the wiring pattern, but it is preferred that the thermal expansion coefficients are identical. When the thermal expansion coefficients are identical, not only the wiring pitch can be designed assuming that the thermal expansion coefficient in the vicinity of the connecting portion is close to that of the material for the wiring pattern material, but also the expansion coefficient of the film can be brought close to that of the wiring pattern material, with a result that wire breaking during the cooling-heating cycle based on the difference in the thermal expansion coefficient of the film and that of the wiring pattern material can be prevented. In the light of the above, the material constituting the wiring pattern and that constituting the dimension retention pattern are more preferably identical, and most preferably both of them are a copper metal.

The dimension retention pattern, as described above, may be formed on the same surface as that on which the wiring pattern has been formed. In this case, it is preferred that the material constituting the dimension retention pattern is identical with that constituting the wiring pattern, since it would permit the formation of the dimension retention pattern simultaneously with the formation of the wiring pattern in the same step. The dimension retention pattern may be formed on the surface (back surface) opposite to the surface on which the wiring pattern has been formed. In such a case, since the wiring pattern has been insulated through a flexible insulating film, there is no concern over short-circuit between wirings, and it is also possible to dispose them directly under or in the vicinity of the semiconductor chip mounting portion or the connecting portion of external devices (display panels).

As illustrated, the dimension retention pattern may be formed throughout the entire surface in a solid form, or may be formed only in a part of the patterned region such as in a grid form or a mesh form.

The dimension retention pattern may have projecting portions constituting portions parallel to the wiring as in FIGS. 2(a), (c), (d), and FIG. 3(a). In such a case, a larger dimension retention pattern can be designed, and therefore dimensional stability can be enhanced. Furthermore, since the projecting portions become dummy patterns from the etching or plating of inner leads, the etching or plating of the inner lead portion can be rendered more uniform.

Preparation of COF

The COF tape of the present invention may be produced by a method of casting a resin on a metal layer in which, for example, a polyimide precursor varnish is applied onto a metal foil such as a copper foil, and then heated to be imidated, a method of growing a metal layer on a flexible insulating film in which, for example, a metal is directly metallized on a flexible insulating film such as a polyimide film by means of vapor deposition etc. and then a metal layer is formed to a predetermined thickness by electrolytic plating, a method in which a flexible insulating film such as a polyimide film and a metal foil are prepared, which are then adhered via a suitable adhesive such as a polyimide adhesive, or the like.

Subsequently, a wiring pattern can be formed by such a method as the semi-additive method, the subtract method, and the additive method. As described above, the dimension retention pattern is preferably formed simultaneously with the wiring pattern in the same step.

### EXAMPLES

### Working Example 1

A copper layer was formed at a thickness of 4 μm by sputtering on the entire surface of a polyimide film (Kapton EN (trade name), manufactured by DuPont) with a thickness of 38 μm. Onto this copper layer a photoresist film was attached, which was exposed to light and developed in a wiring pattern so as to expose the copper layer in a wiring pattern image. Onto the exposed copper layer, copper was electrolytically plated at thickness of 14 μm. Subsequently, the resist was exfoliated and removed in an alkaline aqueous solution, and then the film was immersed in an etching solution comprising an aqueous ferric chloride solution for etching, and the copper layer of the portions that were not plated was removed to fabricate 64 COF tapes were prepared in this way a COF tape having a copper wiring layer on a polyimide film. The constitution of the COF tape obtained was as follows:

Control Sample (Having No Dimension Pattern)

Polyimide film: 38 μm

Thickness of the copper pattern: 12 μm

Width of the copper pattern: 20 μm

Lead pitch: 50 μm

Number of leads: 250

Cumulative pitch (total pitches): 12500 μm

In an entirely similar manner, a COF tape was produced and a dimension retention pattern was also formed on the same surface in the same step at the same thickness as the copper pattern as shown in FIG. 2(a).

### SAMPLE OF THE PRESENT INVENTION

Polyimide film: 38 μm

Thickness of the copper pattern: 12 μm

Width of the copper pattern: 20 μm

Lead pitch: 50 μm

Number of leads: 250

Cumulative pitch (total pitches): 12500 μm

Dimension retention pattern (a=100 μm, b=900 μm, c=25 μm).

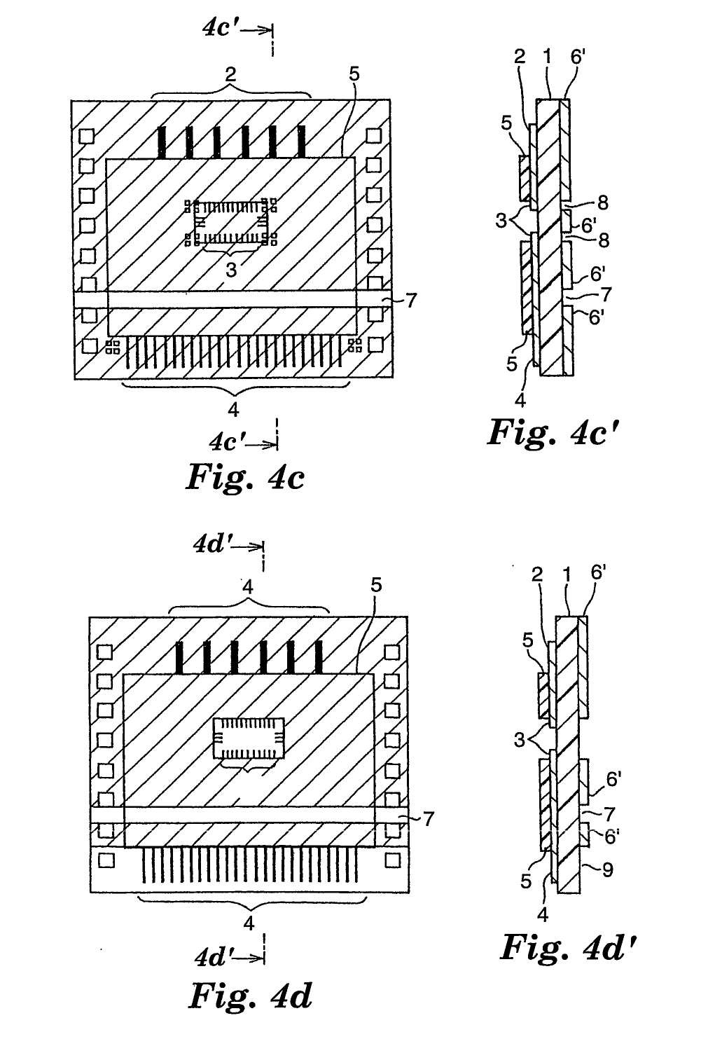

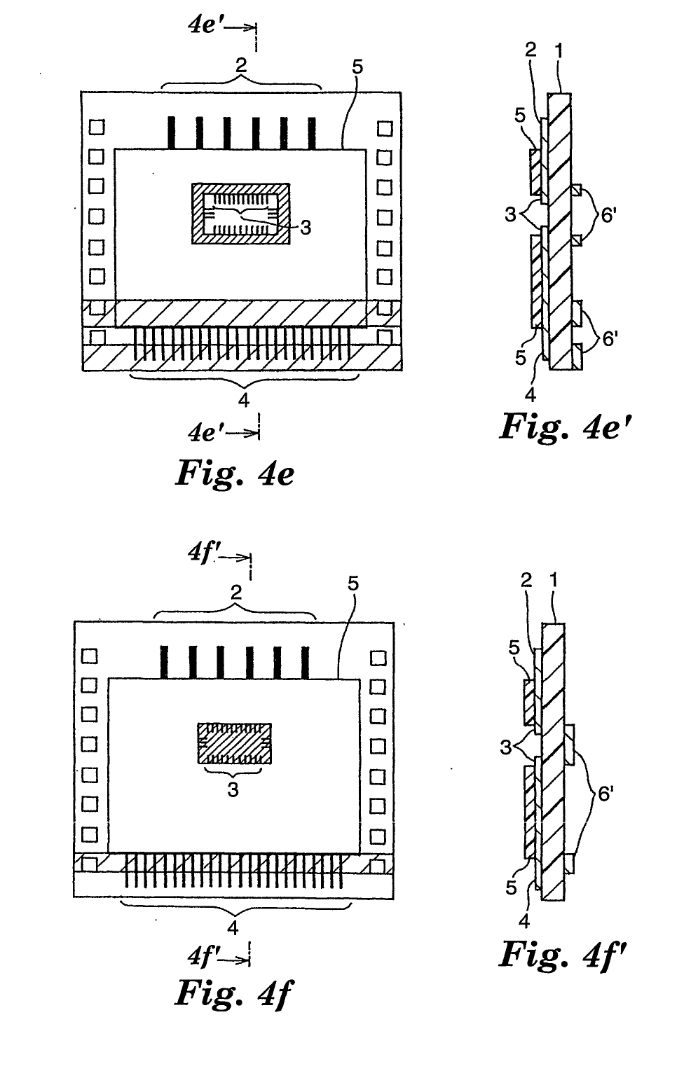

The results of investigation on dimensional changes of these samples before and after etching are shown in FIG. 5 (the control sample) and FIG. 6 (the sample of the present invention). It has already been known that these polyimide films exhibit dimensional changes of about 0.03% on an average when the copper layer is completely removed therefrom. In the figures, −0.03% is set as LSI (Lower Specification Limit), and +0.03% as USI (Upper Specification Limit). From the results of FIGS. 5 and 6, there was an expansion of 0.02% on an average in the control sample that did not form a dimension retention pattern, and dimensional changes of less than 0.005% were only observed in the samples of the present invention that formed a dimension retention pattern. These results revealed that dimensional changes can be suppressed by forming a dimension retention pattern in the vicinity of the connecting portion (leads).

### Working Example 2 (By Simulation)

Effect of Thickness of the Dimension Retention Pattern and the Thickness of the Polyimide Film on the Thermal Linear Expansion Coefficient of the COF Tape

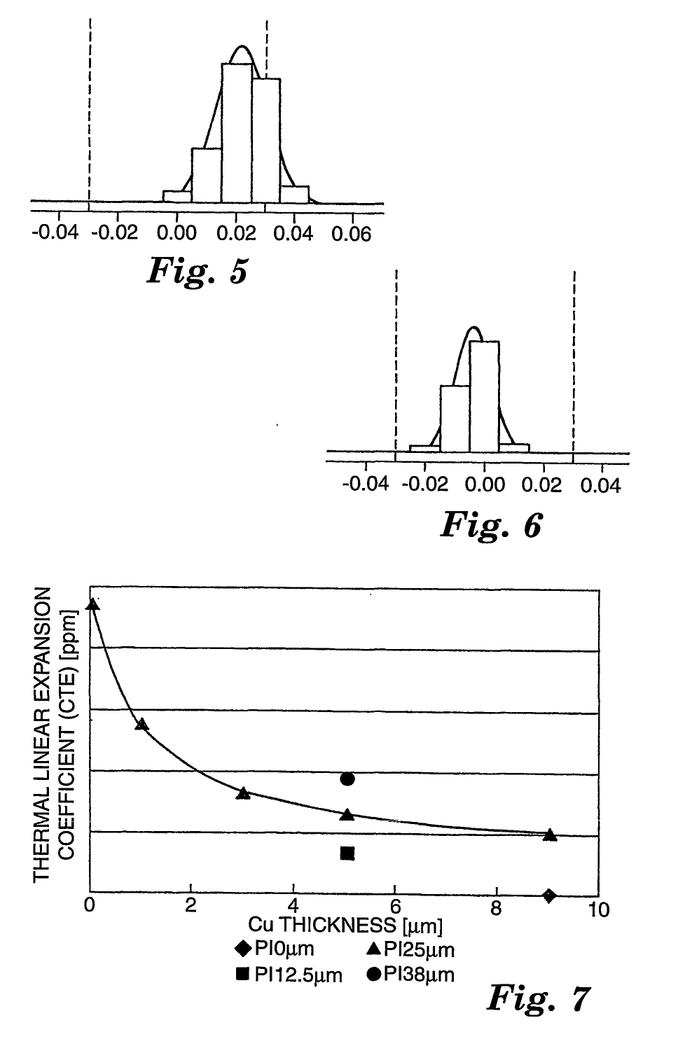

Based on the dimensions and physical values described in the following Table 1, the coefficient of thermal linear expansion of a COF tape was calculated using a finite element analysis program ANSYS. For the thickness of each polyimide, a graph showing the relationship of thickness and thermal linear expansion coefficient of the copper layer is shown in FIG. 7. The figure reveals that the thermal linear expansion coefficient of the COF tape becomes closer to that of copper as the thickness of polyimide becomes thinner. More specifically, when the thickness of the copper dimension retention pattern is 3 μm or more for the 25 μm-thick polyimide film, the thermal linear expansion coefficient of the COF tape becomes closer to that of copper. In this way, by temperature changes during thermal compression bonding with a semiconductor chip, a display panel or a printed circuit board, the COF tape having the dimension retention pattern of copper develops a consistent dimensional changes constrained by the physical properties of copper, and dimensional changes of polyimide during humidity changes are also constrained by the dimension retention pattern of copper, and thus it is less susceptible to humidity changes.

TABLE 1
Table 1: Dimension and physical values used for the calculation
of linear expansion coefficient of the COF tape

| Item | Polyimide | Copper |
|---|---|---|
| Thickness | 12.5, 25, 38 μm | Front side wiring: 5 μm |
| | | Back side dimension |
| | | retention pattern: 1, 3, 5, |
| | | 9 μm |
| Copper wiring | — | L/S = 10/10 μm |
| Thermal linear | 20 ppm | 15 ppm |
| expansion | | |
| coefficient | | |
| Young's modulus | 5.8 × 10⁻⁴ kgf/μm² | 1.3 × 10⁻² kgf/μm² |
| of elasticity | (580 kgf/mm²) | (13236 kgf/mm²) |
| Poisson's ratio | 0.300 | 0.343 |

### Working Example 3 (By Simulation)

Effect of Relieving Stresses of the Wiring Lead by a Dimension Retention Pattern

Based on the physical values described in Table 1, stresses imposed on the wiring lead of the COF tape were calculated using a finite element analysis program ANSYS. It was assumed that the wiring width is 10 μm, the wiring thickness is 5 μm, and the copper dimension retention pattern is formed at a thickness of 5 μm throughout the entire surface (an embodiment of the present invention) opposite to that of the wiring pattern. As a control, stresses are also calculated when the copper dimension retention pattern is not formed. The calculation of the stresses generated on the lead when the temperature was changed by 200° C. gave that they are 1.82×10⁻¹⁰ to 1.78×10⁻⁵ kgf/μm² for the embodiment of the present invention, and, on the other hand, 6.59×10⁻⁸ to 8.5×10⁻⁶ kgf/μm² for the control. The result revealed that the dimension retention pattern can effectively reduce the stresses generated in the lead.

In the COF tape of the present invention, a dimension retention pattern has been formed so as to cross a plurality of lead wirings. Thus, stresses that accumulated during the manufacture of a laminate of a metal layer (for example copper)/a flexible insulating film (for example polyimide) and that remained in the flexible insulating film cannot be released in the vicinity of the inner lead or the outer lead even after the etching removal of the metal layer due to the constraint of the film by the dimension retention pattern. Therefore, the unpredictable dimensional changes of cumulative pitches due to thermal expansion or shrinking of the flexible insulating film can be prevented.

Furthermore, due to the constraint of films by the dimension retention pattern, it is less susceptible to dimensional changes by moisture, and the need for a strict moisture control becomes reduced or obviated.

Furthermore, it is also possible to preliminarily incorporate dimensional changes during heating in designing since the thermal expansion coefficient between cumulative pitches of the COF tape corresponds to that of the dimension retention pattern.

What is claimed is:

1. A chip on flex (COF) tape having a wiring pattern comprising a plurality of wirings arranged in parallel formed on the surface of a flexible insulating film, wherein
a dimension retention pattern is formed on said surface of said flexible insulating film and/or the surface of the side of the film opposite thereto so as to cross the width direction of at least two of said wirings arranged in parallel in the vicinity of the connecting portion of said wiring pattern with a semiconductor chip and/or with an external device.

2. The chip on flex (COF) tape according to claim 1 wherein said dimension retention pattern is formed on the same surface as that on which said wiring pattern of said flexible insulating film is formed in the vicinity of the connecting portion of said wiring pattern with a semiconductor chip and/or the connecting portion with an external device.

3. The chip on flex (COF) tape according to claim 1 wherein said dimension retention pattern is formed on the surface opposite to that on which said wiring pattern of said flexible insulating film is formed in the vicinity of the connecting portion of said wiring pattern with a semiconductor chip and/or the connecting portion with an external device.

4. The chip on flex (COF) tape according to claim 1 wherein said dimension retention pattern is formed at the same time as said wiring pattern.

5. The chip on flex (COF) tape according to claim 3 wherein said dimension retention pattern is formed on a part of the surface opposite to said surface of said flexible insulating film, and a dimension retention pattern is not present at the portion where said flexible insulating film is bent.
